(19) United States
(12) Patent Application Publication
(10) Pub. No.: US 2017/0352757 A1
(43) Pub. Date: Dec. 7, 2017

(54) FIELD EFFECT TRANSISTOR WHICH CAN BE BIASED TO ACHIEVE A UNIFORM DEPLETION REGION

(71) Applicant: Alfred I. Grayzel, Park City, UT (US)

(72) Inventor: Alfred I. Grayzel, Park City, UT (US)

(21) Appl. No.: 15/613,707

(22) Filed: Jun. 5, 2017

Related U.S. Application Data
(60) Provisional application No. 62/392,508, filed on Jun. 3, 2016.

(51) Int. Cl. H01L 29/78; H01L 27/06; H01L 29/10; H01L 29/812; H01L 29/808

(52) U.S. Cl. CPC H01L 29/7831; H01L 29/1045; H01L 29/1058; H01L 29/8124; H01L 27/0629; H01L 29/8083; H01L 29/8122; H01L 29/7827

(57) ABSTRACT

A Field Effect Transistor including: a channel with one end designated the source and the other end designated the drain; a means for connecting to said source end of said channel; a means for connecting to said drain end of said channel; a gate divided into a plurality of segments each insulated from one another; a means for adjusting the bias of each of said segments independently of one another, whereby the depletion region in said channel can be adjusted to avoid pinch-off and to maximize the efficiency of said Field Effect Transistor.

### CROSS REFERENCE TO RELATED APPLICATIONS

This application claims priority to and the benefit of U.S. Provisional Application No. 62/392,508, filed Jun. 3, 2016, and entitled “Field Effect Transistor Which has a Uniform Depletion Region Across its Length and Hence Does Not Experience Pichoff,” which application is incorporated by reference herein in its entirety.

### FIELD OF INVENTION

This invention relates to Field Effect Transistors.

### BACKGROUND OF THE INVENTION

A Field Effect Transistor by prior art has a channel whose resistance is a function of the gate voltage. All Field Effect transistors have a semiconductor channel with one end labeled the source and the second end labeled the drain. In addition all Field Effect transistors have a gate whose voltage controls the resistance of the channel. Current flowing through the channel is therefore a function of the gate voltage. The gate voltage controls the resistance by creating a depletion region across the channel. In the depletion region there are no majority carriers; just minority carriers. The width of the depletion region along the channel is a function of the gate voltage. There are FETs that have two channels and two gates. Each of the gates controls the resistance of one of the channels.

Under normal operation a voltage is applied to the gate here-to-for referred to as the gate voltage, which is comprised of an RF signal and a DC bias voltage here-to-for referred to as the bias. Said bias is used to set the average value of the gate voltage.

FETs include but are not limited to n-type JFET, p-type JFET, MOSFET, NMOSFET, PMOSFET NMOSFET, MNOSFET, DIGMOSFET, HIGFET, TFET, HEMPT, and the CMOSFET in the enhancement mode and in the depletion mode.

FIG. 1A illustrates a Junction Field Effect Transistor (JFET) according to prior art. It shows as an example a schematic of an idealized n-type JFET fabricated by the standard epitaxial process. The active region of the device consists of a lightly doped n-type channel 10 sandwiched between a highly doped p⁺ region 12 and a highly doped p⁺ region 14. A gate terminal 18 is connected to a metal gate electrode 20 which makes electrical contact with the p+ region 14. The p+ region 14 forms a p-n junction with the lightly doped n-type channel 10. The highly doped p+ region 12 makes electrical contact with a metal back electrode 16. A source terminal 22 is connected to a metal source electrode 24 which makes electrical contact with the n-type channel 10. A drain terminal 26 is connected to a metal drain electrode 28, which makes electrical contact with the n-type channel 10.

For the n-type JFET, for normal operations the gate is biased with a negative voltage. A p-n junction is back biased when the p side is negative with respect to the n side of the junction. A negative voltage on the gate terminal 18 back-biases the p-n junction comprised of the p⁺ region 14 and the lightly doped n-type channel 10. Back-biasing this junction causes a depletion region whose width is a function of the negative voltage applied to the gate terminal 18. Thus varying the negative voltage on the gate terminal 18 changes the width of the depletion region, which causes the resistance of the lightly doped n-type channel 10 to vary. A positive voltage in the lightly doped n-type channel 10, will also back-bias the p-n junction comprised of the p⁺ region 14 and the lightly doped n-type channel 10.

FIG. 1B shows the voltage distribution along the lightly doped n-type channel 10 for the JFET shown in FIG. 1A, when a positive direct current (DC) voltage is applied to the drain terminal 26 by a seven volt battery 30 and the source terminal 22 and the metal back electrode 16 are connected to ground. The voltage in the lightly doped n-type channel 10 due to the seven volt drain voltage back-biases the p-n junction which is comprised of the p⁺ region 14 and the lightly doped n-type channel 10. This back-bias is greatest at the drain, where the voltage in the lightly doped n-type channel 10 is seven volts and is least at the source where the voltage in the lightly doped n-type channel 10 is zero volts. The voltage drop from the metal source electrode 24 to the start of the depletion region and the voltage drop from the metal drain electrode 28 to the end of the depletion region have been neglected to simplify this discussion. The back bias: due to the drain voltage, causes a depletion region along the channel. In the depletion region the majority carriers; electrons in the case of the n-type JFET, are removed and only minority carriers remain. The larger the back-bias the greater will be the width of the depletion region and therefore, the higher the resistance of the channel. Thus the width of the depletion region and therefore, the resistance of the channel will be greatest at the drain and will be smallest at the source. The change in voltage per unit length in the lightly doped n-type channel 10 varies; as shown in FIG. 1B, since the resistance of the channel varies due to the variation of the width of the depletion region.

The drain voltage; the DC voltage applied to the drain terminal 26 in FIG. 1A, which causes the lightly doped n-type channel 10 in FIG. 1A to be completely depleted just at the drain is defined as V_{Dsat} and this condition is called pinch-off. FIG. 1C shows the depletion region 36 for the JFET shown in FIG. 1A when a battery 32 whose voltage is equal to V_{Dsat} is connected to drain terminal 26 and the source terminal 22 and the metal back electrode 16 are grounded. The pinch-off point is defined as the point at which pinch-off occurs closest to the source. The pinch-off point 40, is shown in FIG. 1C for the case where the drain voltage equals V_{Dsat}.

If the drain voltage is increased by ΔV the pinch-off point moves towards the source a distance ΔL to a new position 42. FIG. 1D shows the depletion region 36 for the JFET shown in FIG. 1A when a battery 34 whose voltage is equal to V_{Dsat}+ΔV is connected to drain terminal 26 and the source terminal 22 and the metal back electrode 16 are grounded. The depletion region 36 is enlarged so that over a region of length ΔL from the pinch-off point 42 to the end of the depletion region 44, the channel is completely depleted; only minority carriers remain and therefore, the resistance is very large. The drain current flows through this depleted region of length ΔL resulting in large losses in this high resistance region. These losses reduce the efficiency of the JFET. When the drain voltage is greater than V_{Dsat} the drain current saturates; the drain current does not increase with increased drain voltage.

FIG. 2 shows an n-type enhancement mode MOSFET according to prior art. It consists of a lightly doped p-type semiconductor 90 which makes electrical contact with a metal back electrode 108. A gate terminal 92 is connected to a metal gate electrode 94. A thin insulating layer 96 insulates the metal gate electrode 94 from the lightly doped p-type semiconductor 90. A source terminal 98 is connected to a metal source electrode 99 which makes electrical contact with a source highly doped n⁺ island 100. The source highly doped n⁺ island 100 makes electrical contact with the lightly doped p-type semiconductor 90 forming a p-n junction. A drain terminal 102 is connected to a metal drain electrode 104 which makes electrical contact with a drain highly doped n⁺ island 106. The drain highly doped n⁺ island 106 makes electrical contact with the lightly doped p-type semiconductor 90 forming a p-n junction. The purpose of said p-n junctions is to restrict the drain current to flow from said source end of the channel to said drain end of said channel.

An n-type enhancement mode MOSFET must be biased by a positive gate voltage. The metal gate electrode 94, the thin insulating layer 96 and the lightly doped p-type semiconductor 90 together form an n-type MOS capacitor. When a sufficiently large positive voltage is applied to the gate electrode 92, electrons start to accumulate in the lightly doped p-type semiconductor 90 at its interface with insulating layer 96, forming an n channel from source to drain. Increasing the gate voltage attracts more electrons to this channel thereby reducing the resistance of the channel. A positive DC drain voltage applied to the drain terminal 102 creates a voltage distribution in the lightly doped p-type semiconductor 90 similar to that shown in FIG. 1B for the JFET. This voltage reduces the affect of the gate voltage reducing the number of electrons in the channel. The drain voltage applied to terminal 102 in FIG. 2, which causes the channel to be completely depleted of electrons just at the drain is defined as V_{Dsat} and this condition is called pinch-off. The pinch-off point is defined as the point at which pinch-off first occurs. If the drain voltage is increased by ΔV, the pinch-off point moves towards the source a distance ΔL as in the JFET. Over the region of length ΔL, the channel is completely devoid of electrons and therefore, the resistance is very large. The drain current flows through this region resulting in large losses. These losses reduce the efficiency of the MOSFET.

In prior art for all FETs, when a voltage V_{dsat} is applied from the drain to the source in all FETs the channel will pinch-off causing a loss in efficiency.

### SUMMARY OF THE INVENTION

The FET of the present invention is superior because there is no pinch-off and hence no high resistance region of length ΔL. This is accomplished by dividing the gate electrode into segments which are insulated from one another and can be biased separately. By biasing each segment separately it is possible to compensate for the voltage distribution along the channel due to the drain voltage thus minimizing the depletion region and eliminating pinch-off. Minimizing the depletion region results in greater efficiency than can be obtained by prior art.

In accordance with the present invention an FET where the gate is divided into segments which can each be biased separately. Attached is Appendix I as “Analyze RF JFETs for Large-Signal Behavior,” published Jan. 23, 2017, which is incorporated by reference in its entirety.

### BRIEF DESCRIPTION OF THE DRAWINGS

In the drawings, closely related figures have the same number but different alphabetic suffixes.

FIG. 1A shows an n-type JFET according to prior art.

FIG. 1B shows the voltage distribution along the channel for the JFET shown in FIG. 1A, when the drain voltage equals seven volts.

FIG. 1C shows the depletion region in the channel of the JFET when the drain voltage equals V_{Dsat}.

FIG. 1D shows the depletion region in the channel of the JFET when the drain voltage is greater than V_{Dsat}.

FIG. 2 shows an n-type MOSFET according to prior art.

FIG. 3A is an embodiment of the present invention; as an n-type JFET.

FIG. 3B shows the voltage drop along the channel for the JFET shown in FIG. 3A when a five volt battery is connected to the drain terminal and the source terminal is grounded.

FIG. 3C is an embodiment of the present invention shown in FIG. 3A where each section of the gate is biased by means of a separate battery.

FIG. 4A is an embodiment of the present invention as an n-type MOSFET.

FIG. 4B shows the voltage drop along the channel for the MOSFET shown in FIG. 4A when a five volt battery is connected to the drain terminal.

FIG. 4C is an embodiment of the present invention shown in FIG. 4A where each section of the gate is biased by means of a separate battery.

FIG. 4D is an embodiment of the present invention shown in FIG. 4A where each section of the gate is biased by means of two batteries and a resistor network.

FIG. 4E is an embodiment of the present invention shown in FIG. 4A where each section of the gate is biased by means of a battery and a resistor network.

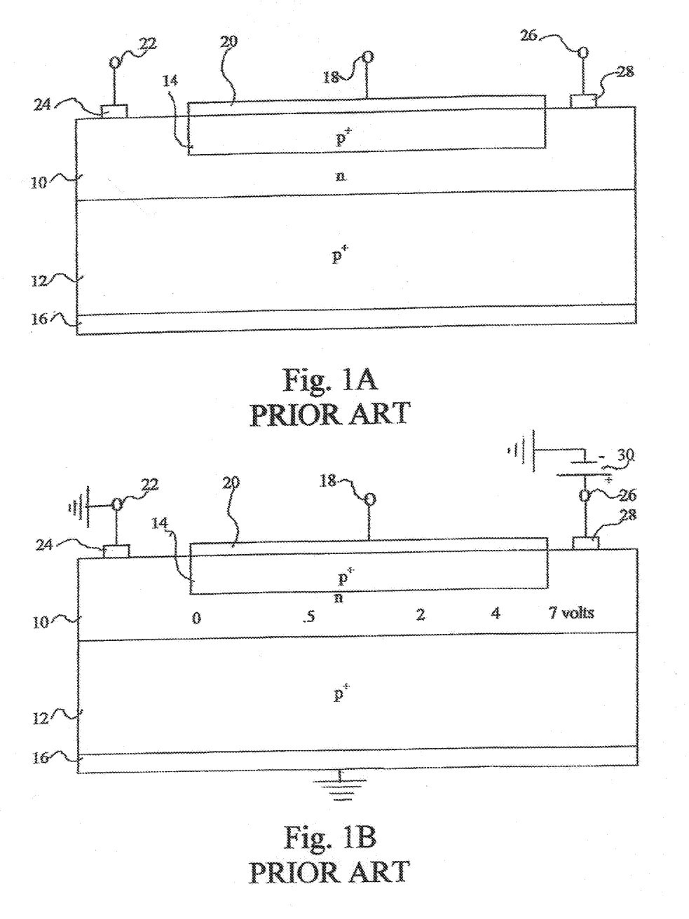

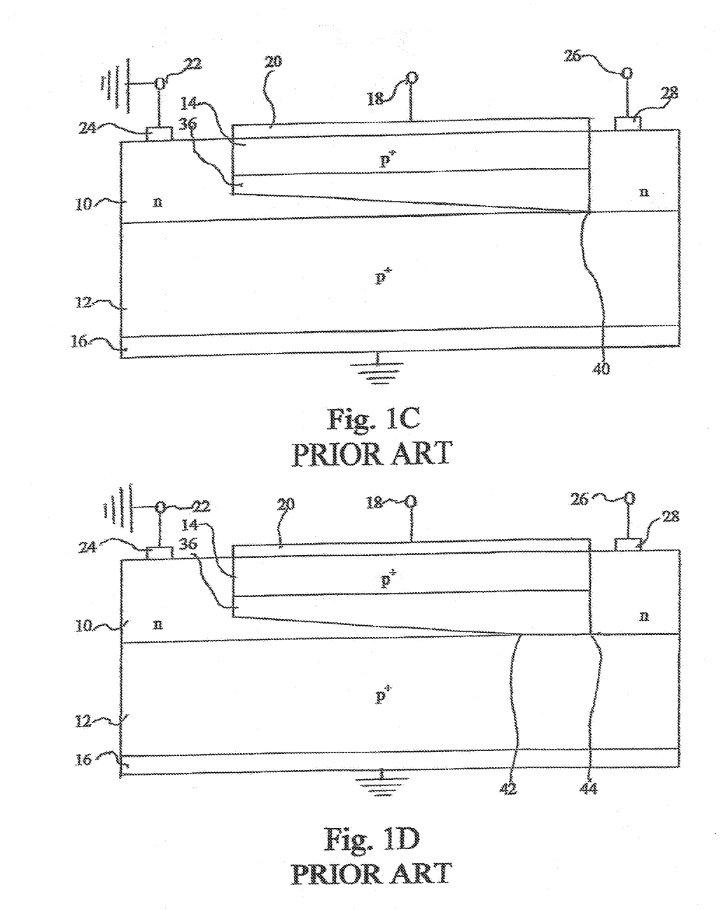

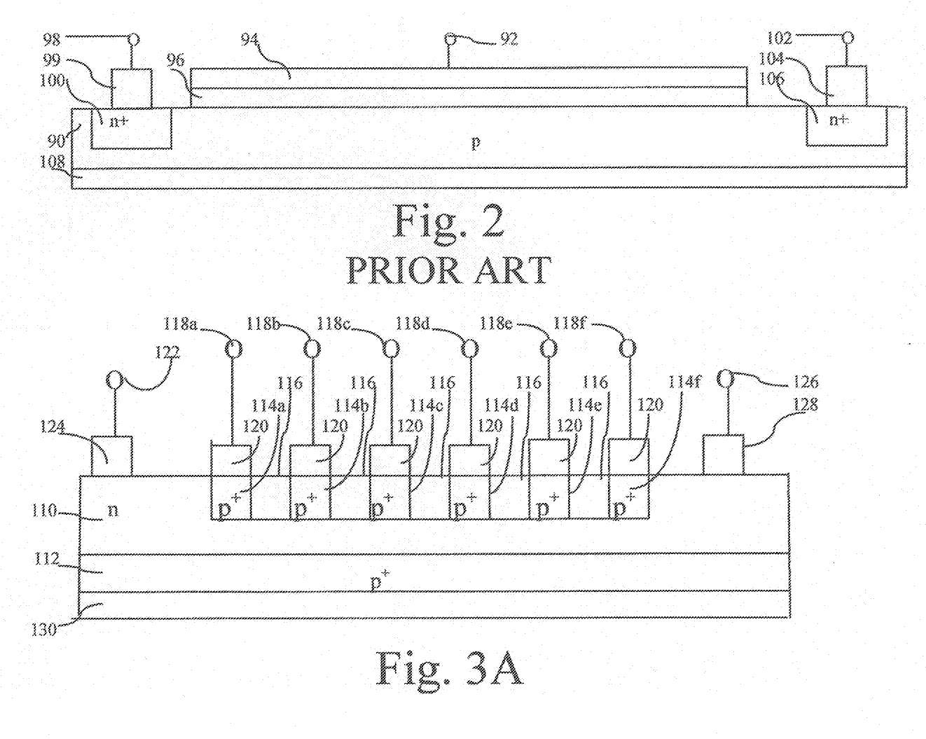

### DETAILED DESCRIPTION OF THE INVENTION—APPLIED TO A JFET

The invention applies to any Field Effect Transistor (FET). Under normal operation of an FET, a voltage is applied to the gate here-to-for referred to as the gate voltage, which is comprised of an RF signal and a DC bias voltage here-to-for referred to as the bias. Said bias is used to set the average value of the gate voltage. According to the present invention the gate of the FET is divided into segments which are insulated from one another and can be biased separately. The present invention is applicable to any FET such as but not limited to n-type JFET, p-type JFET, MOSFET, NMOSFET, PMOSFET, CMOSFET, MNOSFET, DIGMOSFET, HIGFET, TFET and HEMPT, in the enhancement mode and in the depletion mode and FETs with multiple channels and with multiple gates where one or more of the gates is divided into segments as described above.

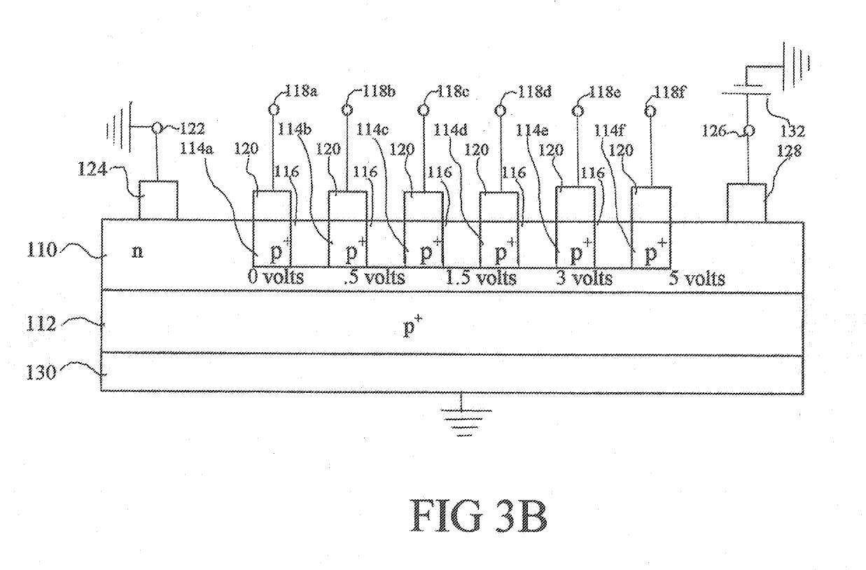

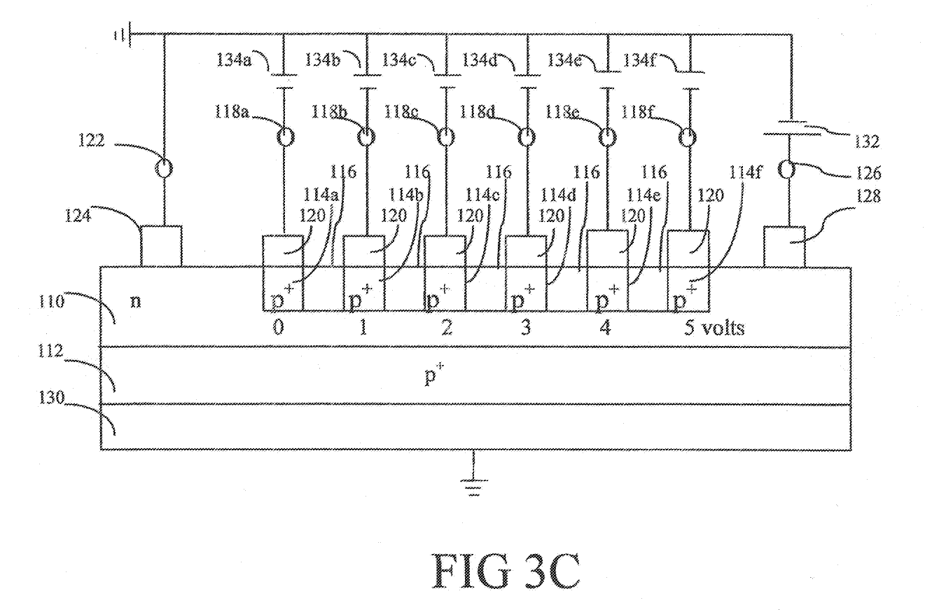

FIG. 3A shows a JFET according to this invention where N; the number of segments, is equal to six for this example. The active region of the device consists of a lightly doped n-type channel 110 making electrical contact with a highly doped p⁺ region 112 and forming N, p-n junctions with N, p⁺ regions 114a, 114b, 114c, 114d, 114e and 114f The N, p⁺ regions are each insulated from adjacent p⁺ regions by an insulator 116. There are N-1, p⁺ regions 116. N is equal to six as an example in FIG. 3A. The highly doped p+ region 112 makes electrical contact with a metal back electrode 130. A source terminal 122 is connected to a metal source electrode 124 which makes electrical contact with the n-type channel 110. A drain terminal 126 is connected to a metal drain electrode 128 which makes electrical contact with the n-type channel 110. N gate terminals 118a, 118b, 118c, 118d, 118e and 118f are each connected to a separate metal gate electrode 120 which makes electrical contact with the p+ regions 114a, 114b, 114c, 114d, 114e and 114f. There are N separate gate electrodes 120. N is equal to six in this exemplary example.

A JFET having the form of FIG. 3A operates as follows:

Source terminal 122, connected to a metal source electrode 124 which makes electrical contact with the n-type channel 110 provides a means for connecting electrically to said source end of said n-type channel 110. Drain terminal 126 connected to a metal drain electrode 128 which makes electrical contact with the n-type channel 110 provides a means for connecting electrically to said drain end of said n-type channel 110. Gate terminal 118a connected to a metal gate electrode 120, which makes electrical contact with the p+ region 114a, gate terminal 118b connected to a metal gate electrode 120, which makes electrical contact with the p+ region 114b, gate terminal 118c connected to a metal gate electrode 120, which makes electrical contact with the p+ region 114c, gate terminal 118d connected to a metal gate electrode 120, which makes electrical contact with the p+ region 114d, gate terminal 118e connected to a metal gate electrode 120, which makes electrical contact with the p+ region 114e and gate terminal 118f connected to a metal gate electrode 120, which makes electrical contact with the p+ region 114f, provide a means for connecting electrically to each segment of the gate. A different voltage can be applied to each gate terminal 118a through 118f allowing each of the segments of the gate to be biased independently of one another.

FIG. 3B shows the approximate voltage distribution along the lightly doped n-type channel 110 for the JFET shown in FIG. 3A, when a voltage is applied to the drain terminal 126, by a five volt battery 132 and the source terminal 122 and the metal back electrode 130 are connected to ground. The change in voltage per unit length in the channel varies since the resistance of the channel varies due to the variation of the width of the depletion region caused by the five volt battery 132 connected to drain terminal 126. The voltage in the lightly doped n-type channel 110, due to the five volt drain voltage shown in FIG. 3B, back-biases the p-n junctions. Since each of the N, p-n junctions can be biased separately the N, p-n junctions can be biased to counter act the voltage distribution along the lightly doped n-type channel 110 shown in FIG. 3B. The depletion region will then be uniform and pinch-off will not occur.

FIG. 3C shows an embodiment of the invention of the JFET according to the invention shown in FIG. 3A where each gate terminal is biased with a separate DC voltage source. A battery 132 with voltage V_{d} is connected to the drain terminal 126, where V_{d} equals five volts in the example shown in FIG. 3C. The source terminal 122 and metal back terminal 130 are grounded as shown in FIG. 3C. There are N gate terminals 118a through 118f where N equals six in the example shown in FIG. 3C. Each of the N, gate terminals is biased separately, such that the voltage across each p-n junction; comprised of one of the p+ regions 114a, 114b, 114c, 114d, 114e and 114f and the lightly doped n-type channel 110, is equal to V0 where V0<0. The first gate terminal 118a is biased by a battery 134a with a voltage V0. The second gate terminal 118b is biased by a battery 134b with a voltage V0+Δ where Δ is equal to V_{d}/(N-1). For the example shown in FIG. 3C, Δ equals one. The third gate terminal is biased by a battery 134c with a voltage V0+2Δ and each successive gate terminal is biased by a battery with a voltage increased by Δ.

A biasing arrangement in the form of FIG. 3C operates as follows:

If each of the gate terminals is biased such that all of the p-n junctions are back biased by the same voltage V0, the depletion region will have the same width at each p-n junction and the change in voltage per unit length in the channel will be approximately constant, as shown in FIG. 3C. For instance, the bias voltage at gate terminal 118d due to battery 134d which biases the fourth p-n junction is V0+3 and the voltage in the channel at the fourth p-n junction is 3 volts. The fourth p-n junction is therefore back biased with voltage V0. As a result of all the p-n junctions being biased with the same voltage the width of the depletion region is the same all along the channel and pinch-off does not occur.

In the above example it was assumed that the change in voltage per unit length in the channel was constant, and therefore each successive gate terminal was biased by a battery with a voltage increased by Δ. The batteries can be adjusted from there nominal values when the change in voltage per unit length in the channel is not constant. The biasing arrangement according to this invention can be adjusted such that each p-n junction is back biased with the voltage V0.

The biasing arrangement shown in FIG. 3C is applicable to any FET and is shown in FIG. 3C for a JFET as an example.

### DETAILED DESCRIPTION OF THE INVENTION—APPLIED TO A MOSFET

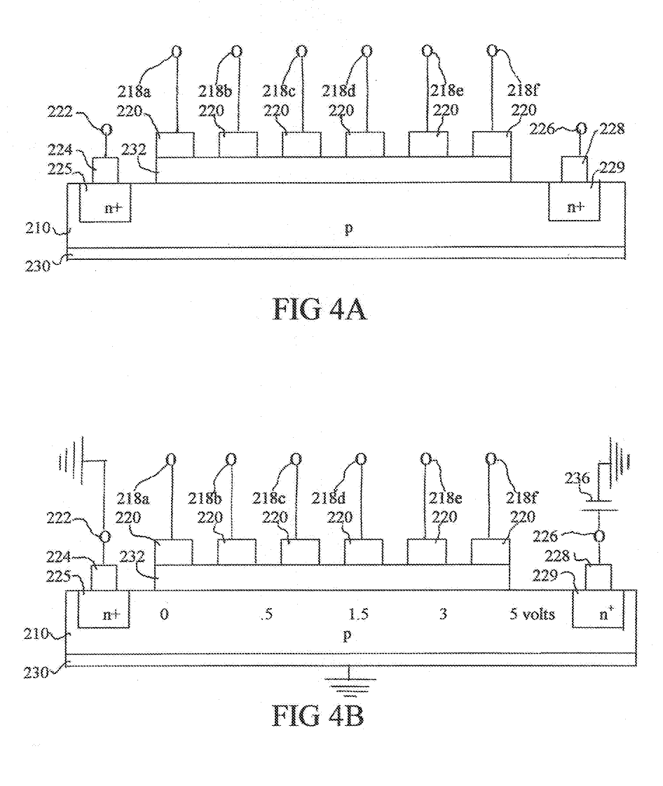

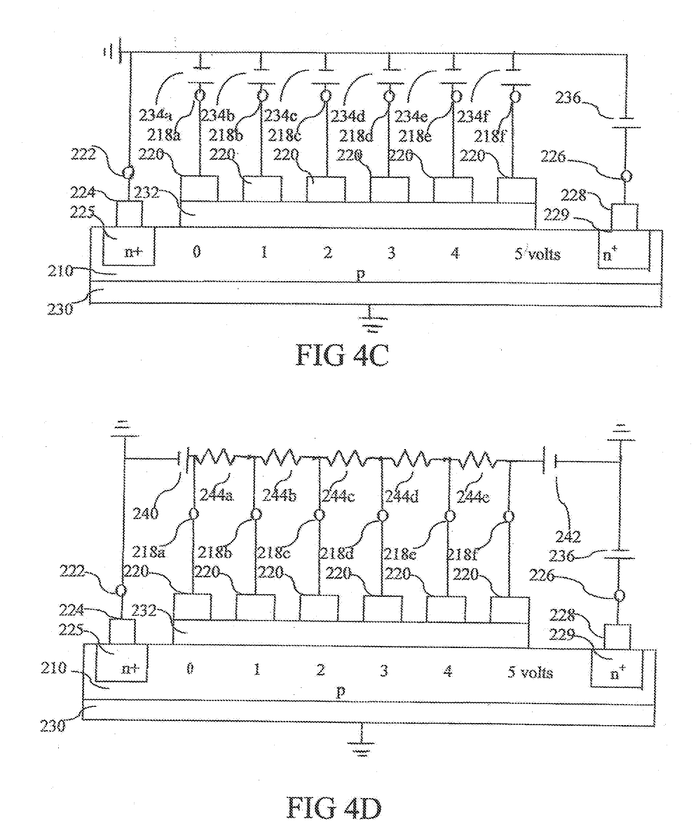

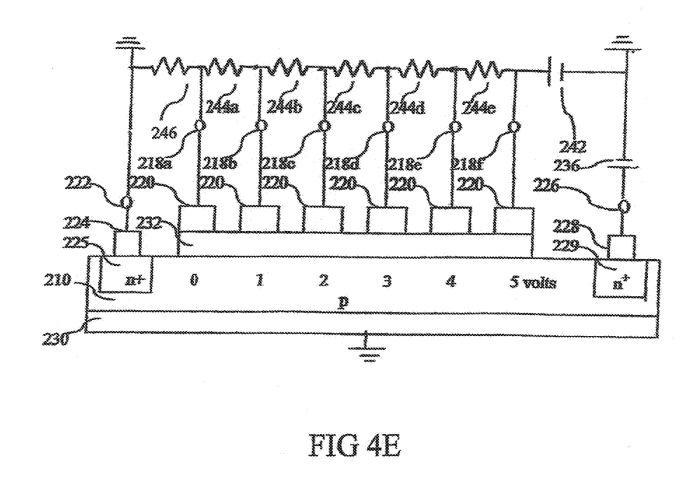

FIG. 4A shows an n-type enhancement mode MOSFET according to this invention where N equal six for this example. The active region of an n-type MOSFET consists of a lightly doped p-type semiconductor 210 which makes electrical contact with a metal back electrode 230. A source terminal 222 is connected to a metal source electrode 224 which makes electrical contact with a source highly doped n⁺ island 225. The source highly doped n⁺ island 225 makes electrical contact with the lightly doped p-type semiconductor 210 forming a p-n junction. A drain terminal 226 is connected to a metal drain electrode 228 which makes electrical contact with a drain highly doped n⁺ island 229. The drain highly doped n⁺ island 229 makes electrical contact with the lightly doped p-type semiconductor 210 forming a p-n junction. N, gate terminals 218a, 218b, 218c, 218d, 218e and 218f are each connected to a separate metal gate electrode 220. There are N separate gate electrodes, where N is equal to six as an example in FIG. 4A. A thin insulating layer 232 insulates each of the N metal gate electrodes 220, from the lightly doped p-type semiconductor 210. Each of the metal gate electrodes 220 combined with the insulating layer 232 and the lightly doped p-type semiconductor 210 forms an MOS capacitor.

A MOSFET having the form of FIG. 4A operates as follows:

Source terminal 222, connected to a metal source electrode 224; which makes electrical contact with the source highly doped n⁺ island 225, provides a means for connecting electrically to said source end of said p-type channel 210. Drain terminal 226, connected to a metal drain electrode 228; which makes electrical contact with the drain highly doped n⁺ island 229, provides a means for connecting electrically to said drain end of said p-type channel 210. N gate terminals 218a, 218b, 218c, 218d, 218e and 218f, each connected to a separate metal gate electrode 220, provide a means for connecting electrically to each segment of said gate. N is equal to six as an example in FIG. 4A. A different voltage can be applied to each gate terminal 218a through 218f allowing each of the segments of the gate to be biased independently of one another.

An n-type enhancement mode MOSFET must be biased with a positive gate voltage. FIG. 4B shows an approximate voltage distribution along the lightly doped p-type channel 210 for the MOSFET shown in FIG. 4A, when a voltage is applied to the drain terminal 226, by a five volt battery 236 and the source terminal 222 and the metal back electrode 230 are connected to ground. The change in voltage per unit length in the channel varies since the resistance of the channel varies. This is due to the variation of the width of the depletion region which widens going down the channel from source to drain. The voltage in the lightly doped p-type channel 210, due to the five volt drain voltage, back-biases the MOS capacitors. Since each of the N, MOS capacitors can be biased separately the N, p-n junctions can be biased to counter act the voltage distribution along the lightly doped p-type channel 210 shown in FIG. 4B. The depletion region will then be uniform and pinch-off will not occur.

FIG. 4C shows an embodiment of the invention of the MOSFET according to the invention shown in FIG. 4A where each gate terminal is biased with a separate DC voltage source. A battery 236 with voltage V_{d} is connected to the drain terminal 226, where V_{d} equals five volts in the example shown in FIG. 4C. The source terminal 222 and the metal back terminal 230 are grounded as shown in FIG. 4C. There are N gate terminals 218a through 218f where N equals six as an example in FIG. 4C. Each of the N, gate terminals is biased separately, such that the voltage across each MOS capacitor is V0, where V0>0. The first gate terminal 218a is biased by a battery 234a with a voltage V0. The second gate terminal 218b is biased by a battery 234b with a voltage V0+Δ where Δ is equal to V_{d}/(N-1). V_{d}/(N-1) equals one in the example shown in FIG. 4C. The third gate terminal is biased by a battery 234c with a voltage V0+2Δ and each successive gate terminal is biased by a battery with a voltage increased by Δ.

A biasing arrangement in the form of FIG. 4C operates as follows:

If the biasing is such that all of the MOS capacitors are back biased by the same voltage V0, the depletion region will have the same width at each MOS capacitor and the change in voltage per unit length in the channel will be approximately constant, as shown in FIG. 4C. The bias voltage for instance at gate terminal 218d due to battery 234d which biases the fourth MOS capacitor is V0+3 and the voltage in the channel at the fourth MOS capacitor is 3 volts. The fourth MOS capacitor is therefore back biased with a voltage V0. As can be seen from FIG. 4C, all of the MOS capacitors are back biased with the voltage V0. As a result the width of the depletion region is the same all along the channel and pinch-off does not occur.

In the above example it was assumed that the change in voltage per unit length in the channel was constant, and therefore each successive gate terminal was biased by a battery with a voltage increased by 4. The batteries can be adjusted from there nominal values when the change in voltage per unit length in the channel is not constant. The biasing arrangement according to this invention, can be adjusted such that each MOS capacitor is back biased with the voltage V0. The biasing arrangement shown in FIG. 4C is applicable to any FET and is shown as an example in FIG. 4C for a MOSFET.

FIG. 4D shows an embodiment of the invention of the MOSFET according to the invention shown in FIG. 4A where all of the MOS capacitors are biased with a bias voltage of V0, by two batteries and a resistor network. For the example shown in FIG. 4D, N equals six and V0 equals 2 volts. A battery 236 with voltage V_{d} is connected to the drain terminal 226, where V_{d} equals five volts in the example shown in FIG. 4D. The source terminal 222 and metal back terminal 230 are grounded. There are N gate terminals 218a through 218f. A two volt battery 240 is connected between gate terminal 218a and ground. A seven volt battery 242 is connected between gate terminal 218f and ground. A resistor 244a of value R is connected between gate terminal 218a and gate terminal 218b. R should be a large value of resistance to minimize the power used by the bias network. A resistor 244b of value R is connected between gate terminal 218b and gate terminal 218c. A resistor 244c of value R is connected between gate terminal 218c and gate terminal 218d. A resistor 244d of value R is connected between gate terminal 218d and gate terminal 218e. A resistor 244e of value R is connected between gate terminal 218e and gate terminal 218f.

A biasing arrangement in the form of FIG. 4D operates as

follows: Battery 240 biases gate terminal 218a at 2 volts while battery 242 biases gate terminal 218f at 7 volts. There is a five volt voltage drop between gate terminals 218a and 218f, resulting in a one volt drop across each of the five resistors. Gate terminal 218b is therefore biased at three volts. Gate terminal 218c is therefore biased at four volts. Gate terminal 218d is therefore biased at five volts. Gate terminal 218e is therefore biased at six volts. The change in voltage per unit length in the channel is approximately constant when all of the MOS capacitors are back-biased with the same voltage since the depletion region will have the same width at each MOS capacitor. The voltage distribution in the channel when the change in voltage per unit length in the channel is constant is shown in FIG. 4D. The bias voltage for instance at gate terminal 218d is five volts which biases the fourth MOS capacitor and the voltage in the channel at this MOS capacitor is 3 volts. This MOS capacitor therefore, is back biased by a voltage of 2 volts. As can be seen from FIG. 4D, all of the MOS capacitors are back biased with a voltage of 2 volts. As a result the width of the depletion region is the same all along the channel and pinch-off does not occur.

In the above example it was assumed that the change in voltage per unit length in the channel was constant, and therefore each of the resistors have the same value. The values of the resistors can be adjusted from there nominal values when the change in voltage per unit length in the channel is not constant. The biasing arrangement according to this invention can be adjusted such that each MOS capacitor is back biased with the voltage V0. The biasing arrangement shown in FIG. 4D is applicable to any FET and is shown in FIG. 4D as an example for a MOSFET.

FIG. 4E shows an embodiment of the invention of the MOSFET according to the invention shown in FIG. 4A where all of the MOS capacitors are biased with a bias voltage equal to V0, by one battery and a resistor network. For the example shown in FIG. 4E, N equals six and V0 equals 2 volts. A battery 236 with voltage V_{d} is connected to the drain terminal 226, where V_{d} equals five volts in the example shown in FIG. 4E. The source terminal 222 and metal back terminal 230 are grounded. There are N gate terminals 218a through 218f. A seven volt battery 242 is connected between gate terminal 218f and ground. A resistor 244a of value R is connected between gate terminal 218a and gate terminal 218b. R should be a large value of resistance to minimize the power used by the bias network. A resistor 244b of value R is connected between gate terminal 218b and gate terminal 218c. A resistor 244c of value R is connected between gate terminal 218c and gate terminal 218d. A resistor 244d of value R is connected between gate terminal 218d and gate terminal 218e. A resistor 244e of value R is connected between gate terminal 218e and gate terminal 218f. A resistor 246 of value 2R (2 times R) is connected between gate terminal 218a and ground.

A biasing arrangement in the form of FIG. 4E operates as follows: Battery 242 biases gate terminal 218f at 7 volts. There is a five volt voltage drop between gate terminals 218a and 218f, and a 2 volt drop across resistor 246 to ground, resulting in a one volt drop across each of the five resistors 244a, 244b, 244c, 244d and 244e. Gate terminal 218a is therefore biased at two volts. Gate terminal 218b is therefore biased at three volts. Gate terminal 218c is therefore biased at four volts. Gate terminal 218d is therefore biased at five volts. Gate terminal 218e is therefore biased at six volts. The change in voltage per unit length in the channel is approximately constant when all of the MOS capacitors are back-biased with the same voltage since the depletion region will have the same width at each MOS capacitor. The voltage distribution in the channel when the change in voltage per unit length in the channel is constant is shown in FIG. 4E. The bias voltage for instance at gate terminal 218d is five volts and the voltage in the channel at this MOS capacitor is 3 volts. This MOS capacitor is therefore, back biased by a voltage of 2 volts. As can be seen from FIG. 4E, all of the MOS capacitors are back biased with a voltage of 2 volts. As a result the width of the depletion region is the same all along the channel and pinch-off does not occur.

In the above example it was assumed that the change in voltage per unit length in the channel was constant, and therefore each of the five resistors 244a, 244b, 244c, 244d and 244e have the same value R and resistor 246 has a value of 2R (2 times R). The values of the resistors can be adjusted from there nominal values when the change in voltage per unit length in the channel is not constant. The biasing arrangement according to this invention can be adjusted such that each MOS capacitor is back biased with the voltage V0. The biasing arrangement shown in FIG. 4E is applicable to any FET and is shown in FIG. 4E as an example for a MOSFET.

A Field Effect Transistor by prior art has a channel whose resistance is a function of the gate voltage. All Field Effect transistors have a semiconductor channel with one end labeled the source and the second end labeled the drain. In addition all Field Effect transistors have a gate whose voltage controls the resistance of the channel. Current flowing through the channel is therefore a function of the gate voltage. The gate voltage controls the resistance by creating a depletion region across the channel. In the depletion region there are no majority carriers; just minority carriers. The width of the depletion region along the channel is a function of the gate voltage. A positive voltage in the n-type channel will also affect the width of the depletion region. When a positive DC voltage is applied from the drain to the source a positive voltage distribution occurs in the channel which also affects the width of the depletion region. The drain voltage causes the greatest depletion at the drain end of the channel. The drain voltage which causes a channel to be completely depleted just at the drain is defined as V_{Dsat} and this condition is called pinch-off. The pinch-off point is defined as the point at which pinch-off occurs closest to the source.

If the drain voltage is increased beyond V_{Dsat} the pinch-off point moves towards the source a distance ΔL to a new position. The depletion region is enlarged so that over a region of length ΔL the channel is completely depleted; only minority carriers remain and therefore, the resistance is very large. The drain current flows through this depleted region of length ΔL resulting in large losses in this high resistance region. These losses reduce the efficiency of the JFET.

Under normal operation a voltage is applied to the gate, which is comprised of an RF signal and a DC bias voltage. The bias voltage is used to set the average value of the gate voltage.

There are FETs that have two channels and two gates. Each of the gates controls the resistance of one of the channels

In prior art for all FETs, when a voltage V_{dsat} is applied from the drain to the source in all FETs the channel will pinch-off causing a loss in efficiency.

The FET of the present invention is superior because there is no pinch-off and hence no high resistance region of length ΔL. This is accomplished by dividing the gate electrode into segments which are insulated from one another and can be biased separately. By biasing each segment separately it is possible to compensate for the voltage distribution along the channel due to the drain voltage thus minimizing the depletion region and eliminating pinch-off Minimizing the depletion region results in greater efficiency than can be obtained by prior art. The invention applies to any Field Effect Transistor.

Accordingly the reader will see that the FETs of this invention can be biased to provide an approximately uniform depletion region across the length of the channel thus eliminating pinch-off and minimizing the depletion region. Therefore, the FETs according to this invention provide maximum efficiency; by maximizing the ratio of output power to input power.

The present invention is applicable to any FET such as but not limited to n-type JFET, p-type JFET, MOSFET, NMOSFET, PMOSFET, CMOSFET, DIGMOSFET, HIGFET, TFET and HEMPT, in the enhancement mode and in the depletion mode and FETs with multiple channels with multiple gates where one or more of the gates is divided into segments as described above.

FETs of this invention allow the biasing of each segment of the gate electrode individually so that a uniform depletion region can be achieved. Methods of biasing each segment can be, but are not limited to:
1—Individual DC voltage sources such as batteries or DC voltage supplies connected to all or some of the gate terminals.
2—A DC voltage source or a plurality of DC voltage sources in combination with a plurality of resistors or a resistor network connected to all or some of the gate terminals.

Although the description above contains many specificities these should not be construed as limiting the scope of the invention but merely providing illustrations of some of the presently preferred embodiments of this invention.

I claim:

1. A Field Effect Transistor comprising:
a channel with one end designated as the source and the other end designated
as the drain,
a means for connecting electrically to the source end of said channel,
a means for connecting electrically to the drain end of said channel,
a gate divided into a plurality of segments each insulated from one another,
a means for connecting electrically to each segment of the gate,
whereby each segment can be biased independently enabling the depletion region in said channel to be adjusted to maximize the efficiency of said Field Effect Transistor.

2. The Field Effect Transistor of claim 1, wherein said means of adjusting the bias of each of said segments comprises a plurality of DC voltage sources and a means to connect one of said DC voltage sources to each of said segments.

3. The Field Effect Transistor of claim 1, wherein said means of adjusting the bias of each of said segments comprises a plurality of terminals each connected to one of said segments, a DC voltage source connected to the terminal connected to the segment closest to said source end of said channel, a DC voltage source connected to the terminal connected to the segment closest to said drain end of said channel and a plurality of resistors said resistors connected between said terminals.

4. The Field Effect Transistor of claim 2 wherein said means of adjusting the bias of said segments, is from the family of Field Effect Transistors designated as JFET, p-type JFET, MOSFET, NMOSFET, PMOSFET NMOSFET, MNOSFET, DIGMOSFET, HIGFET, TFET, HEMPT, and the CMOSFET in the enhancement mode and in the depletion mode.

5. The Field Effect Transistor of claim 3 wherein said means of adjusting the bias of said segments, is from the family of Field Effect Transistors designated as JFET, p-type JFET, MOSFET, NMOSFET, PMOSFET, MNOSFET, DIGMOSFET, HIGFET, TFET, HEMPT, and the CMOSFET in the enhancement mode and in the depletion mode.

6. A Field Effect Transistor from the family of Field Effect Transistors designated as JFET, MOSFET, p-type JFET, NMOSFET, PMOSFET NMOSFET, MNOSFET, DIGMOSFET, HIGFET, TFET, HEMPT, and the CMOSFET in the enhancement mode and in the depletion mode comprising:
a channel with one end designated as the source and the other end designated as the drain,
a means for connecting electrically to said source end of said channel.
a means for connecting electrically to said drain end of said channel,
a gate divided into a plurality of segments each insulated from one another,
a means for connecting electrically to each segment of the gate, whereby each segment can be biased independently enabling the depletion region in said channel to be adjusted to maximize the efficiency of said Field Effect Transistor.

7. The Field Effect Transistor of claim 6, wherein said means of adjusting the bias of each of said segments comprises a plurality of DC voltage sources and a means to connect one of said DC voltage sources to each of said segments.

8. The Field Effect Transistor of claim 6, wherein said means of adjusting the bias of each of said segments comprises a plurality of terminals each connected to one of said segments, a DC voltage source connected to the terminal connected to the segment closest to said source end of said channel, a DC voltage source connected to the terminal closest to said drain end of the channel and a plurality of resistors said resistors connected between said terminals.
